(19) United States
(12) Patent Application Publication
(10) Pub. No.: US 2004/0261690 A1
(43) Pub. Date: Dec. 30, 2004

(54) Method of making optical fluoride crystal feedstock

(76) Inventor: Malcolm N. Ivy, Springfield, MA (US)

Correspondence Address: CORNING INCORPORATED, SP-TI-3-1, CORNING, NY, 14831

(21) Appl. No.: 10/611,506

(22) Filed: Jun. 30, 2003

(51) Int. Cl. C30B 11/00; C30B 9/00; C30B 17/00; C30B 21/02; C30B 28/06

(52) U.S. Cl. 117/81; 117/83

(57) ABSTRACT

A method of making optical fluoride crystal feedstock includes loading a fluoride raw material in powder form into a flexible mold and applying isostatic pressure to the mold to compress the fluoride raw material. The compressed fluoride raw material could be used directly to grow a single or mixed crystal or could be subjected to a pre-melt process prior to being used to grow a crystal.

### BACKGROUND OF INVENTION

The invention relates generally to methods for growing optical fluoride crystals and specifically to a method of preparing feedstock of alkaline-earth and alkali-metal fluorides for use in making optical fluoride crystals.

Crystals of alkaline-earth and alkali metal fluorides are useful in applications requiring high transmission at short wavelengths, e.g., at wavelengths below 200 nm. Single-grained optical fluoride crystals are commonly grown using the Bridgman-Stockbarger process. As shown in FIG. 1A, the process involves loading a fluoride feedstock 100 into a crystal growth crucible 102 inside a hot zone 104 in a vertical furnace 106. The hot zone 104 is then heated to a temperature sufficient to melt the fluoride 100. The molten fluoride 100 is lowered slowly from the hot zone 104 into a cold zone 108 inside the furnace 106. Referring to FIG. 1B, as the crucible 102 passes from the hot zone 104 to the cold zone 108, the molten fluoride 100 goes through a zone of thermal gradient. On passing through this zone, the temperature transition inside the molten fluoride 100 creates a crystal front 110, which propagates inside the crucible 102, within the molten fluoride 100, as long as the crucible 102 is caused to move downwardly.

The fluoride feedstock is typically made by pre-melting relatively pure fluoride powder (or granules) and rapidly solidifying the pre-melt. Typically, a solid oxide scavenger, such as lead or zinc fluoride, is added to the fluoride prior to pre-melting the fluoride. The main purpose of the pre-melt process is to increase the bulk density of the fluoride powder so that more fluoride can be packed into the crystal growth crucible for each furnace cycle. This makes it possible to make a larger crystal without altering the size of the crystal growth crucible. For example, the pre-melt process can increase the bulk density of CaF₂ powder from 1.1 gm/cc to approximately 2.2 gm/cc. The pre-melt process typically takes between 12 and 15 days and occupies a furnace that could otherwise be used for actual growth of the crystal. Further, to facilitate melting during the actual crystal growth, the solidified pre-melt body has to be crushed before it is loaded into the crystal growth crucible. This crushing action is often a source of metallic and other forms of contamination.

From the foregoing, there is desired a method of preparing a feedstock of alkaline-earth and alkali metal fluorides for making optical fluoride crystals. Preferably, the method reduces the production time of optical fluoride crystals and/or increases the throughput of the furnace for each production run. Preferably, the method does not introduce a significant amount of impurities into the feedstock.

### SUMMARY OF INVENTION

In one aspect, the invention relates to a method of making optical fluoride crystal feedstock which comprises loading a fluoride raw material in powder form into a flexible mold and applying isostatic pressure to the mold to compress the fluoride raw material.

In another aspect, the invention relates to a method of making an optical fluoride crystal which comprises loading a fluoride raw material in powder form into a flexible mold, applying isostatic pressure to the mold to compress the fluoride raw material, loading the compressed fluoride raw material into a crucible, and growing a crystal by melting the compressed fluoride raw material inside the crucible and moving the crucible through a thermal gradient.

In another aspect, the invention relates to a method of making an optical fluoride crystal which comprises loading a fluoride raw material in powder form into a flexible mold, applying isostatic pressure to the mold to compress the fluoride raw material, melting the compressed fluoride raw material and solidifying the melt to form a sold pre-melt body, crushing the solid pre-melt body, and growing a crystal by melting the crushed pre-melt and moving the melt through a thermal gradient.

Other features and advantages of the invention will be apparent from the following description and the appended claims.

### BRIEF DESCRIPTION OF DRAWING

FIGS. 1A and 1B illustrate a process for forming a crystal.

FIG. 2A illustrates a system for isostatic pressing of fluoride powder according to one embodiment of the invention.

FIG. 2B shows the fluoride powder being compressed inside a mold.

FIG. 2C shows the compressed fluoride powder after isostatic pressing.

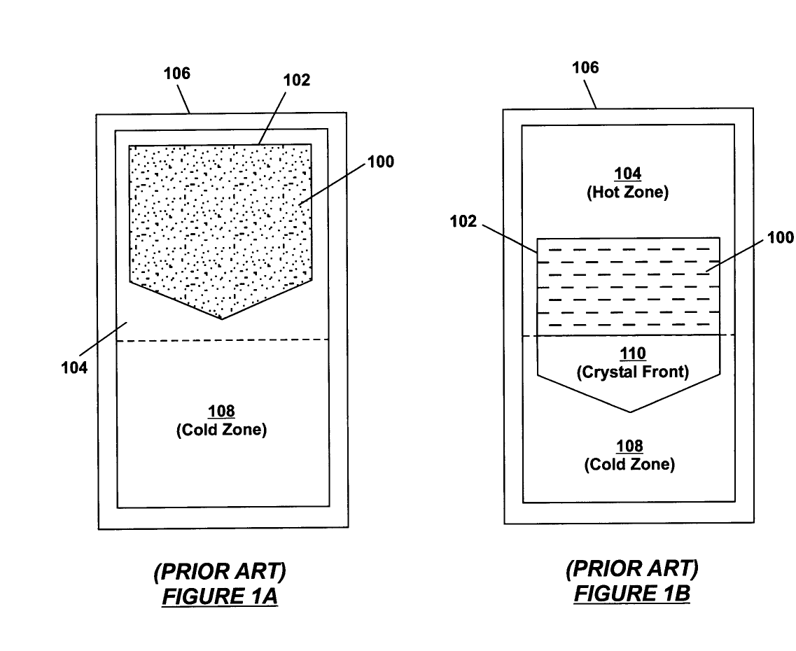

### DETAILED DESCRIPTION OF PREFERRED EMBODIMENTS

The invention will now be described in detail with reference to a few preferred embodiments, as illustrated in accompanying drawings. In the following description, numerous specific details are set forth in order to provide a thorough understanding of the invention. It will be apparent, however, to one skilled in the art, that the invention may be practiced without some or all of these specific details. In other instances, well-known features and/or process steps have not been described in detail in order to not unnecessarily obscure the invention. The features and advantages of the invention may be better understood with reference to the drawings and discussions that follow.

In accordance with one embodiment of the invention, a method of preparing a feedstock of alkaline-earth and alkali metal fluorides includes isostatic pressing of relatively pure alkaline-earth and alkali-metal fluorides. Cold, warm, or hot isostatic pressing may be used to prepare the feedstock. Preferably, the feedstock is produced by cold isostatic pressing. The method can be used to prepare feedstock for single-grained crystals, such as CaF₂, BaF₂, MgF₂, SrF₂, LiF, and NaF. These single-grained crystals have low-wavelength absorption edges and are suitable for use in optical applications requiring high transmission at wavelengths below 200 nm. The method can also be used to prepare feedstock for mixed crystals. For example, the method could be used to prepare feedstock for mixed crystals having the general formula M₃AlF₆, where M is selected from the group consisting of Li, Na, K, Rb, and Cs. The method could be extended to the preparation of feedstock for mixed crystals of general formula (M₁)ₓ(M₂)₁₋ₓF₂, where M₁ and M₂ are different and are selected from the group consisting of Ca, Ba, Mg, Sr, Li and Na; and x is in the range of 0<x<1, preferably in the range 0.01<x<0.99. The method can be further extended to include mixed metal fluorides wherein a metal fluoride selected from the lanthanide series, for example, lanthanum, ytterbium, yttrium or others of the series, is used as one of M₁ or M₂, or is used in addition to M₁ and M₂. Those skilled in the art will recognize the possible combinations.

The main purpose of isostatic pressing is to increase the bulk density of fluoride powder prior to actual crystal growth. For example, the bulk density of relatively pure CaF₂ powder is approximately 1.1 gm/cc. The bulk density of CaF₂ after cold isostatic pressing is approximately 2.5 gm/cc or greater. The bulk density of CaF₂ after a typical pre-melt process is approximately 2.2 gm/cc. Thus, the densification achievable through cold isostatic pressing is comparable to the densification achievable through a pre-melt process, implying that cold isostatic pressing (or other forms of isostatic pressing) could effectively replace the pre-melt stage of the crystal growth process. Advantageously, isostatic pressing can be accomplished in a few minutes. If the pre-melt stage is bypassed, the compressed powder could be loaded directly into the crystal growth crucible without a crushing step that could introduce impurities into the powder. Alternatively, isostatic pressing could be used as a precursor to the pre-melt process. This would increase the throughput of the pre-melt furnace, since it would be possible to load more powder into the pre-melt crucible for each furnace run without changing the size of the pre-melt crucible.

Cold isostatic pressing is a material processing technique where high fluid pressure is applied to powder in a flexible mold at ambient temperature and the powder is uniformly compacted as a result of the action of the fluid pressure. Hot and warm isostatic pressing are analogous to cold isostatic pressing. They involve applying isostatic pressure to the mold at elevated temperatures. There are two types of cold isostatic pressing: “wet-bag” and “dry-bag.” In wet-bag cold isostatic pressing, the mold is filled with powder and then immersed in fluid in a pressure vessel. The mold is removed from the pressure vessel after each cycle and refilled. In dry-bag cold isostatic pressing, the mold is fixed to the pressure vessel and filled with powder in-situ. The mold is typically made of an elastomeric material and forms a barrier between the pressure fluid and the powder. For the present invention, the mold could be shaped such that the compressed powder formed from the isostatic pressing operation can fit directly into a crystal growth or pre-melt crucible.

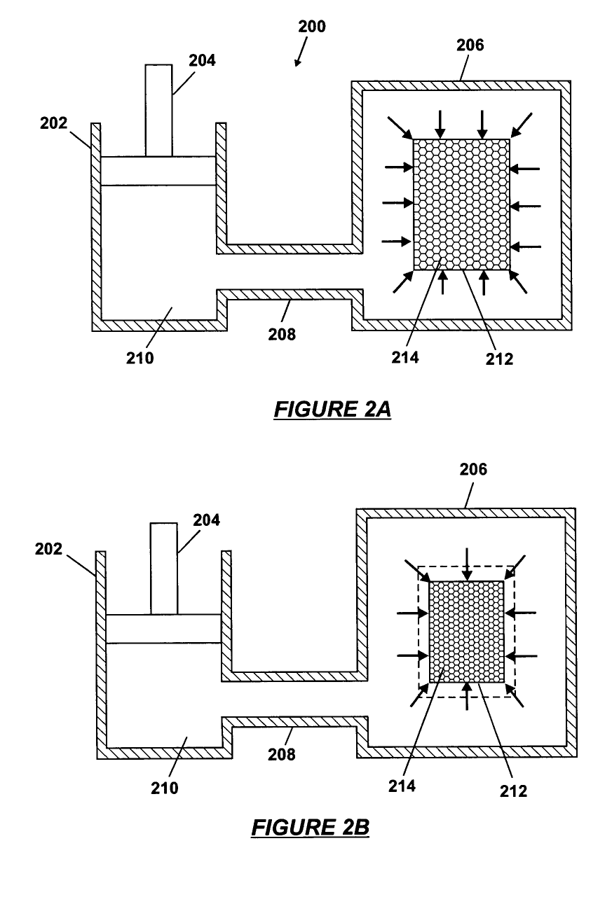

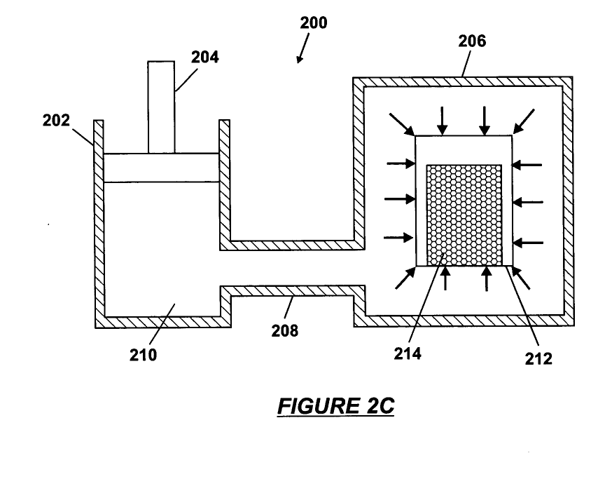

FIG. 2A is an illustration of a system 200 for preparing feedstock of alkaline-earth and alkali metal fluorides according to an embodiment of the invention. The system 200 includes a hydraulic cylinder 202 fitted with a sliding piston 204. The system 200 also includes a pressure vessel 206, which is in fluid communication with the hydraulic cylinder 202, e.g., through a fluid channel 208. Fluid 210 is confined between the hydraulic cylinder 202 and the pressure vessel 206. Typically, fluid 210 is water or oil, but other suitable pressure transmission fluid may also be used. A flexible mold 212 is disposed in the pressure vessel 206. The mold 212 is filled with fluoride powder 214. For transmission applications, the fluoride powder 214 should be relatively pure, i.e., substantially free of impurities that can have a detrimental effect on transmission, such as oxide impurities. An oxide scavenger, typically a fluoride compound, such as lead or zinc fluoride, may be mixed with the fluoride powder 214 in the mold 212. Typically, only a small amount of the oxide scavenger is needed, e.g., 0.5 to 2% of lead or zinc fluoride is typically sufficient to reduce the oxygen content of the fluoride powder to an acceptable level prior to crystal growth. The mold 212, which is in contact with the fluoride powder 214, should not serve as a source of impurities. Preferably, the mold 212 is made of a material (such as polyvinyl chloride) that will not have a detrimental effect on transmission and should be sanitized prior to use. The mold may also advantageously be made of a fluorocarbon material or lined with a fluorocarbon material.

In operation, force is applied to the sliding piston 204, causing the sliding piston 204 to move relative to the hydraulic cylinder 202. The motion of the sliding piston 204 exerts force on the confined fluid 210, which in turn produces a compressive force on the mold 212. The mold 212 is subjected to equal pressure from every side, hence the term isostatic pressing. As the pressure on the mold 212 increases, the mold 212 and the fluoride powder 214 are compressed, as shown in FIG. 2B. After a predetermined time based on the desired compression of the fluoride powder 214, the force applied to the sliding piston 204 is removed, causing the sliding piston 204 to return to its original position. As the sliding piston 204 returns to its original position, the isostatic pressure on the mold 212 returns to ambient conditions, allowing the mold 212 to also return to its original shape. However, the fluoride powder 214 inside the mold 212 remains in its compressed state, as shown in FIG. 2C. This process has been used to increase the bulk density of CaF₂ powder from approximately 1.1 gm/cc to approximately 2.5 gm/cc or more.

The aspect ratio (i.e., diameter to height ratio) of the compressed powder should be selected such that the compressed powder does not fracture while the isostatic pressure action on the mold is returning to ambient conditions. For example, the aspect ratio could range from 1 to 10. The volume of the mold would be selected based on the compaction ratio of the fluoride powder 214 and the desired final dimensions of the compressed powder. It may be desirable to remove air trapped in the mold 212, e.g., using a vacuum tube, prior to the pressing operation. If there is air in the mold 212 prior to pressing, the air will become trapped between the particles of the powder during pressing. When the mold 212 starts to return to its original state, the air will exit the compressed powder and occupy the space around the compressed powder inside the mold 212. The speed at which the air escapes the compressed powder depends on how fast the isostatic pressure is allowed to return to ambient conditions and the aspect ratio of the compressed powder. A larger aspect ratio means more surface area from which the air can escape. If the air escapes the compressed powder too fast, the compressed powder may fracture. However, by removing the air from the mold 212 prior to pressing, there will be less of a force on the compressed powder when the isostatic pressure is returning to ambient conditions.

In one embodiment of the invention, feedstock for growing an optical fluoride crystal is made by loading the compressed powder into a pre-melt crucible, pre-melting the compressed powder, and rapidly solidifying the pre-melt. The solid pre-melt body is then crushed and stored in an inert environment for later use. Typically, the crusher is a metal hammer, which can introduce metallic impurities into the crushed pre-melt. To reduce the level of metal contamination in the crushed pre-melt, the crushed pre-melt could be passed through magnetic separators. Other crushing methods known in the art can also be used, with due precautions taken to avoid contamination. The crushed pre-melt can be used for growing crystals. In this embodiment, the isostatic pressing operation assists the pre-melt process because more powder can be packed into the pre-melt crucible when the powder is in a compressed state than when the powder is in a loose state, leading to an increase in the yield of the pre-melt furnace.

In another embodiment of the invention, the compressed powder is used directly as feedstock for growing an optical fluoride crystal. That is, the pre-melt stage, including the crushing operation, is bypassed. Because the compressed powder has high density, sufficient powder can be packed into the crystal growth crucible, allowing larger crystals to be produced per furnace run. In this case, the mold 212 could be shaped such that the compressed powder has a net shape that can fit directly into the crystal growth crucible. The compressed powder is preferably stored in an inert atmosphere prior to use in growing a crystal, preferably a dry inert atmosphere. The advantages of this embodiment include substantial reduction in time required to produce the feedstock and elimination of the crushing action, which can introduce contaminants into the feedstock. The crystal can be grown using Bridgman-Stockbarger process or other suitable crystal growth process.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method of making optical fluoride crystal feedstock, comprising:
loading a fluoride raw material in powder form into a flexible mold; and
applying isostatic pressure to the mold to compress the fluoride raw material.

2. The method of claim 1, further comprising mixing a fluorinating agent in powder form with the fluoride raw material prior to applying isostatic pressure to the mold.

3. The method of claim 1, wherein isostatic pressure is applied to the mold at ambient temperature.

4. The method of claim 1, further comprising evacuating air out of the mold prior to applying isostatic pressure to the mold.

5. The method of claim 1, further comprising melting the compressed fluoride raw material and solidifying the melt to form a solid pre-melt body.

6. The method of claim 5, further comprising crushing the solid pre-melt body and storing the crushed pre-melt in an inert atmosphere.

7. The method of claim 1, wherein the fluoride raw material comprises a metal fluoride selected from the group consisting of CaF₂, BaF₂, MgF₂, SrF₂, LiF, NaF, M₃AlF₆, and (M₁)ₓ(M₂)₁₋ₓF₂, and mixtures thereof, and where M is selected from the group consisting of Li, Na, K, Rb, and Cs, M₁ and M₂ are selected from the group consisting of Ca, Br, Mg, Sr, Li, Na, and lanthanide series metal fluorides, and x is in a range from 0 to 1.

8. The method of claim 7, wherein the fluoride raw material further comprises a lanthanide series metal fluoride mixed with the metal fluoride.

9. The method of claim 1, further comprising storing the compressed fluoride raw material in an inert atmosphere.

10. A method of making an optical fluoride crystal, comprising:
loading a fluoride raw material in powder form into a flexible mold;
applying isostatic pressure to the mold to compress the fluoride raw material;
loading the compressed fluoride raw material into a crucible; and
growing a crystal by melting the compressed fluoride raw material inside the crucible and moving the crucible through a thermal gradient.

11. The method of claim 10, further comprising mixing a fluorinating agent in powder form with the fluoride raw material prior to applying isostatic pressure to the mold.

12. The method of claim 10, wherein isostatic pressure is applied to the mold at ambient temperature.

13. The method of claim 10, further comprising evacuating air out of the mold prior to applying isostatic pressure to the mold.

14. The method of claim 10, wherein the fluoride raw material comprises a metal fluoride selected from the group consisting of CaF₂, BaF₂, MgF₂, SrF₂, LiF, NaF, M₃AlF₆, and (M₁)ₓ(M₂)₁₋ₓF₂, and lanthanide series metal fluorides, and mixtures thereof, and where M is selected from the group consisting of Li, Na, K, Rb, and Cs, M₁ and M₂ are selected from the group consisting of Ca, Br, Mg, Sr, Li, Na, and lanthanide series metal fluorides, and x is in a range from 0 to 1.

15. The method of claim 14, wherein the fluoride raw material further comprises a lanthanide series metal fluoride mixed with the metal fluoride.

16. A method of making an optical fluoride crystal, comprising:
loading a fluoride raw material in powder form into a flexible mold;
applying isostatic pressure to the mold to compress the fluoride raw material;
melting the compressed fluoride raw material and solidifying the melt to form a solid pre-melt body;
crushing the solid pre-melt body; and
growing a crystal by melting the crushed pre-melt and moving the melt through a thermal gradient.

17. The method of claim 16, further comprising mixing a fluorinating agent in powder form with the fluoride raw material prior to applying isostatic pressure to the mold.

18. The method of claim 16, wherein isostatic pressure is applied to the mold at ambient temperature.

19. The method of claim 16, further comprising evacuating air out of the mold prior to applying isostatic pressure to the mold.

20. The method of claim 16, wherein the fluoride raw material comprises a metal fluoride selected from the group consisting of CaF₂, BaF₂, MgF₂, SrF₂, LiF, NaF, M₃AlF₆, and (M₁)ₓ(M₂)₁₋ₓF₂, and lanthanide series metal fluorides, and mixtures thereof, and where M is selected from the group consisting of Li, Na, K, Rb, and Cs, M₁ and M₂ are selected from the group consisting of Ca, Br, Mg, Sr, Li, Na, and lanthanide series metal fluorides, and x is in a range from 0 to 1.
